(19) United States
(12) Patent Application Publication
(10) Pub. No.: US 2026/0129980 A1
(43) Pub. Date: May 7, 2026

(54) LAYERED AVALANCHE DETECTOR

(71) Applicant: GlobalFoundries Singapore Pte. Ltd., Singapore (SG)

(72) Inventors: Francesco GRAMUGLIA, Augsburg (DE); Eng Huat Toh, Singapore (SG)

(21) Appl. No.: 18/940,625

(22) Filed: Nov. 7, 2024

(51) Int. Cl. H01L 31/107; H01L 31/072

(52) U.S. Cl. CPC H10F 30/225; H10F 10/16

(57) ABSTRACT

An avalanche photodiode device includes a first doped layer having a first doping type, a second doped layer having a second doping type, a third doped layer having the first doping type, a first PN junction between the first doped layer and the second doped layer, a second PN junction between the second doped layer and the third doped layer, a first vertical conductive structure coupled to the first doped layer and the third doped layer, and a second vertical conductive structure coupled to the second doped layer.

### BACKGROUND

Photodetectors are sensors that detect the presence of electromagnetic radiation. Semiconductor photodiodes are a category of photodetectors that use a P-N diode to convert incident photons into current. Photodiodes are used by many different technologies to sense one or more frequency of light, to determine the time at which transmitted light is reflected back to the photodiode, etc.

Avalanche photodiodes are a highly biased photodiodes in which photo-generated carriers are multiplied by avalanche breakdown in the device. Single-photon avalanche diodes (SPADs) are avalanche photodiodes which are sensitive enough to detect the incidence of a single photon, and have lower timing jitter than typical photodiodes.

Conventional avalanche photodiodes tend to be relatively complex structures that are difficult to fabricate, and the layout of conventional photodiodes limits their fill factor.

### SUMMARY

Embodiments of the present application relate to an avalanche photodiode (APD) device, a photodetector, and a method for forming an APD device.

According to at least some of the embodiments disclosed herein, an avalanche photodiode device includes a first doped layer having a first doping type, a second doped layer having a second doping type, a third doped layer having the first doping type, a first PN junction between the first doped layer and the second doped layer, a second PN junction between the second doped layer and the third doped layer, a first vertical conductive structure coupled to the first doped layer and the third doped layer, and a second vertical conductive structure coupled to the second doped layer.

According to at least some of the embodiments disclosed herein, a photodetector includes at least one avalanche photodiode device which comprises a first doped layer having a first doping type, a second doped layer having a second doping type, a third doped layer having the first doping type, a first PN junction between the first doped layer and the second doped layer, a second PN junction between the second doped layer and the third doped layer, a first vertical conductive structure coupled to the first doped layer and the third doped layer, and a second vertical conductive structure coupled to the second doped layer.

According to at least some of the embodiments disclosed herein, a method for forming an avalanche photodiode device includes forming a first doped layer having a first doping type, forming a second doped layer having a second doping type, forming a third doped layer having the first doping type, forming a first vertical conductive structure coupled to the first doped layer and the third doped layer, and forming a second vertical conductive structure coupled to the second doped layer. A first PN junction is located between the first doped layer and the second doped layer and a second PN junction is located between the second doped layer and the third doped layer.

### BRIEF DESCRIPTION OF THE DRAWINGS

FIG. 1 illustrates a plan view of an embodiment of an avalanche photodiode device.

FIG. 2 is a cross-sectional view of the avalanche photodiode of FIG. 1.

FIGS. 3A to 3F illustrate an embodiment of a process for forming the avalanche photodiode device of FIG. 2.

FIG. 4 illustrates a plan view of an embodiment of an avalanche photodiode device with a pillar.

FIG. 5 is a cross-sectional view of the avalanche photodiode of FIG. 4.

FIG. 6 illustrates an embodiment of an avalanche photodiode array.

FIG. 7 is a cross-sectional view of the avalanche photodiode array of FIG. 6.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and various features are enlarged or diminished for visual clarity.

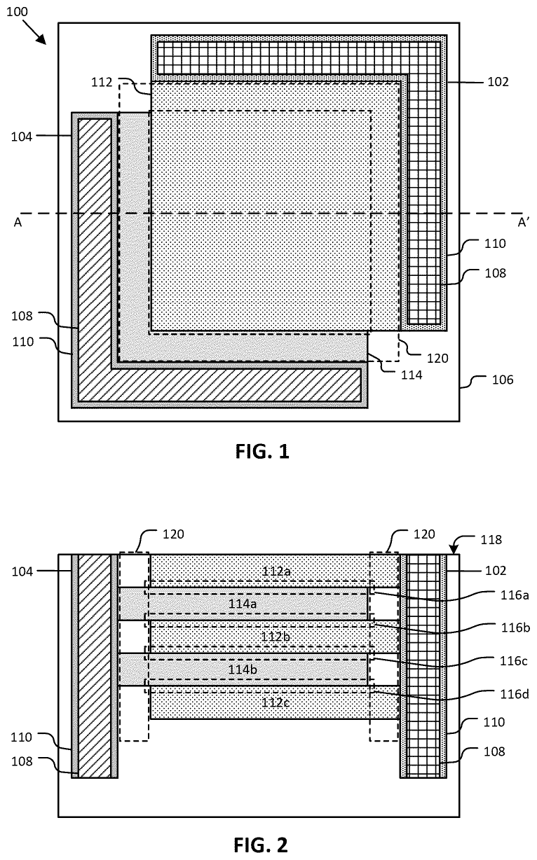

FIG. 1 illustrates a plan view of an avalanche photodiode (APD) device 100 according to an embodiment, and FIG. 2 illustrates a cross-sectional view of the APD device 100 taken along A-A′ of FIG. 1. The avalanche photodiode device 100 may be a single photon avalanche photodiode (SPAD) device.

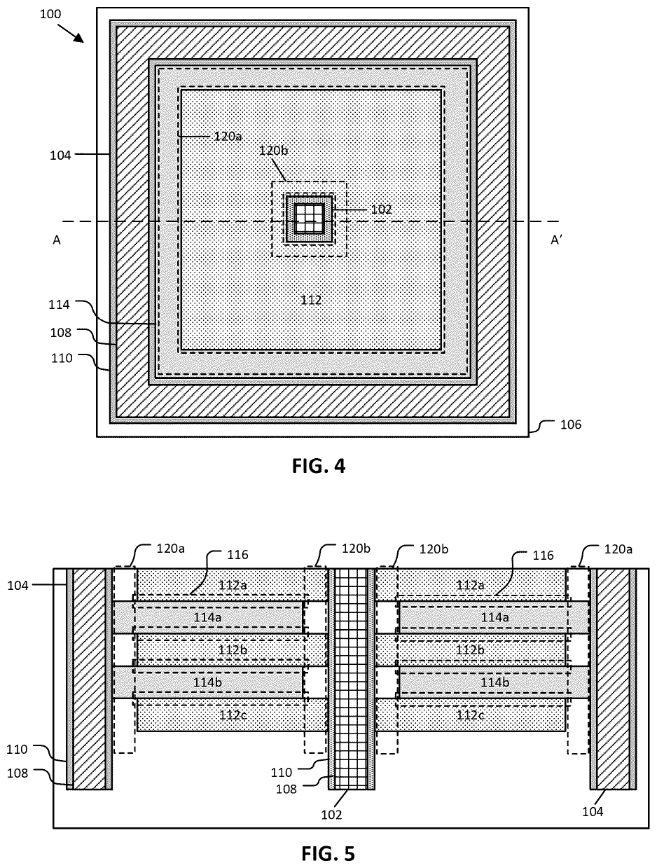

The APD device 100 has a first vertical conductive structure 102 and a second vertical conductive structure 104. In the embodiment of FIG. 1, each of the vertical conductive structures 102 and 104 are trench structures that extend along two sides of the APD device 100. The two trenches may be symmetrical to one another and are formed in semiconductor material 106. In some embodiments, such as the embodiment of FIGS. 4 and 5, a vertical conductive structure 102 or 104 may have a pillar shape. Each of the vertical conductive structures 102 and 104 may be a terminal, e.g. either an anode or a cathode, of the APD device 100. Accordingly, the APD device 100 in FIG. 1 is a two-terminal device.

Each vertical conductive structure 102/104 comprises doped sidewalls 110 with high conductivity and is filled with a conductive material 108. The conductive material 108 may be a doped semiconductor material such as polysilicon which is doped with either P or N dopants. In such an embodiment, the conductive material 108 may have a high dopant concentration on the order of from 10¹⁹/cm³ to 10²⁰/cm³, for example, or on the order of from 10¹⁹/cm³ to 10²¹/cm³. As used herein, “on the order of” refers to an order of magnitude, such that a dopant concentration on the order of 10¹⁹/cm³ includes dopant concentrations of 1*10¹⁹/cm³ to 9*10¹⁹/cm³. The doped sidewalls 110 may have dopant concentrations on the order of from 10¹⁸/cm³ to 10¹⁹/cm³.

In another embodiment, the conductive material 108 may comprise a metal material such as tungsten, copper, etc. When the conductive material 108 is a metal material, the vertical conductive structures 102 and 104 may further comprise a liner layer (not shown). The vertical conductive structures 102 and 104 may have a depth of about 5 to 10 microns, and a width of about 0.5 to 1 micron, for example.

Each vertical conductive structure 102 and 104 may be coupled to a plurality of doped layers. In the embodiment of FIG. 2, first vertical conductive structure 102 is coupled to three doped layers 112a, 112b and 112c, and second vertical conductive structure 104 is coupled to two doped layers 114a and 114b. The dopant type of doped layers 112 is different from the dopant type of doped layers 114. For example, when doped layers 112 have N type dopants, doped layers 114 have P type dopants, and when doped layers 112 have P type dopants, doped layers 114 have N type dopants. A portion of doped layer 114 is shown in FIG. 1 for illustrative purposes, but would otherwise be covered by a portion of semiconductor material 106 as seen in FIG. 2.

The dopant type of a vertical conductive structure, including the doped sidewalls 110 and conductive material 108, may be the same as the dopant type of the doped layers coupled to the vertical conductive structure. For example, when vertical conductive structure 102 has P type doping, the doped layers 112 coupled to vertical conductive structure 102 also have P type doping, and when vertical conductive structure 104 has P type doping, the doped layers 114 coupled to vertical conductive structure 104 also have P type doping.

Dimensions of the doped layers 112 and 114 may be in the micron scale. In various embodiments, the doped layers 112 and 114 may have a width of about 500 nanometers to several microns, and even 10 microns or more. The width of the doped layers 112 and 114 may define a pixel size of the APD device 100. The doped layers may have a rectilinear or square shape as seen in FIG. 1, but embodiments are not limited to that shape. In other embodiments, the doped layers 112 and 114 may have a polygonal, circular, or more generally rounded shape. When the doped layers 112 and 114 have a rounded or circular shape, the width dimensions described above may be diameter dimensions.

Each doped layer 112 and 114 may have a thickness in a range of about 500 nanometers to 1.5 microns, or in a range of about 800 nanometers to 1 micron. As used herein, the term “about” refers to engineering tolerances and normal process variation, which may be plus or minus five percent.

The doped layers 112 and 114 may have a dopant concentration on the order of from 10¹⁷/cm³ to 10¹⁸/cm³, for example, and other embodiments are possible. The surrounding semiconductor material 106 may be lightly doped to a concentration on the order of 10¹⁵/cm³. Accordingly, the semiconductor material 106 may have a low (P- or N-) dopant concentration, the doped layers 112 and 114 may have a higher dopant concentration than the semiconductor material 106, and the doped sidewalls 110 may have a higher dopant concentration than the doped layers.

PN junctions 116, or PN diodes, are present at the interface between each doped layer 112 and doped layer 114. In the embodiment of FIG. 2, a first PN junction 116a is at the interface between doped layer 112a and doped layer 114a, a second PN junction 116b is at the interface between doped layer 112b and doped layer 114a, a third PN junction 116c is at the interface between doped layer 112b and doped layer 114b, and a fourth PN junction 116d is at the interface between doped layer 112c and doped layer 114b.

The specific number and location of doped layers and the corresponding number of PN junctions 116 may vary depending on the intended use of the APD device 100. The wavelength of light detected by an APD device 100 linked to the depth of the PN junction 116 relative to incident surface 118, and the number and depth of PN junctions 116 may be adapted to detect specific wavelengths. An APD device 100 may have as few as a single PN junction 116, and as many as ten or more PN junctions 116, for example. PN junctions 116 may be located closer to incident surface 118 to detect visible light wavelengths, and further from the incident surface 118 to detect near infrared and longer wavelengths.

The incident surface 118 may be a surface of the APD device 100 at which light enters the device. Additional structures such as a lens, a coating, grating, or electrodes (not shown) may be present on the incident surface 118.

A guard ring 120 surrounds the PN junctions 116. The guard ring 120 may comprise a space between each PN junction 116 and the vertical conductive structures 102 and 104 within an APD device 100. As shown in FIG. 2, portions of the doped layers 112 and 114 which are not part of the PN junctions 116 extend through the guard ring 120. The guard ring 120 is between uncoupled edges of doped layers 112 and the second vertical conductive structure 104, and between uncoupled edges of doped layers 114 and the first vertical conductive structure 102.

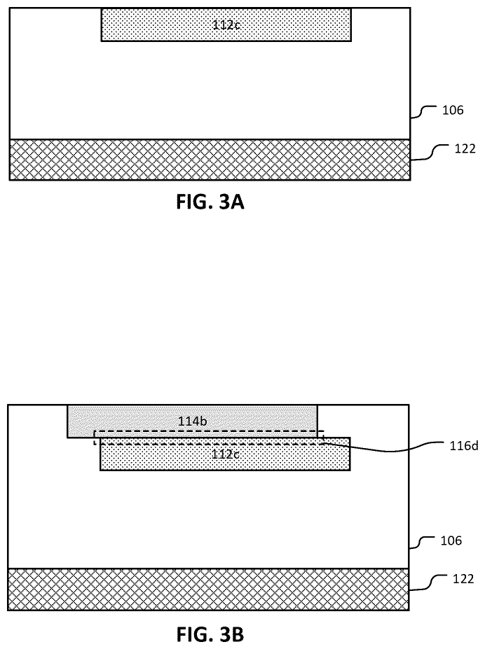

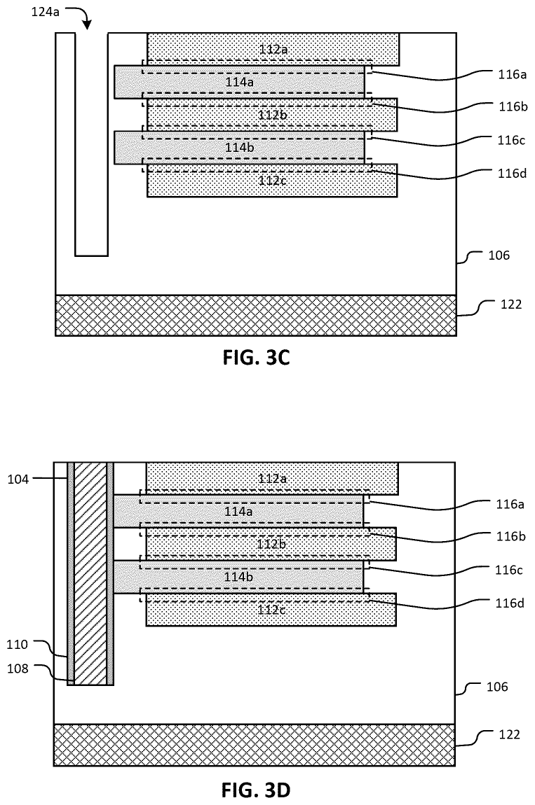

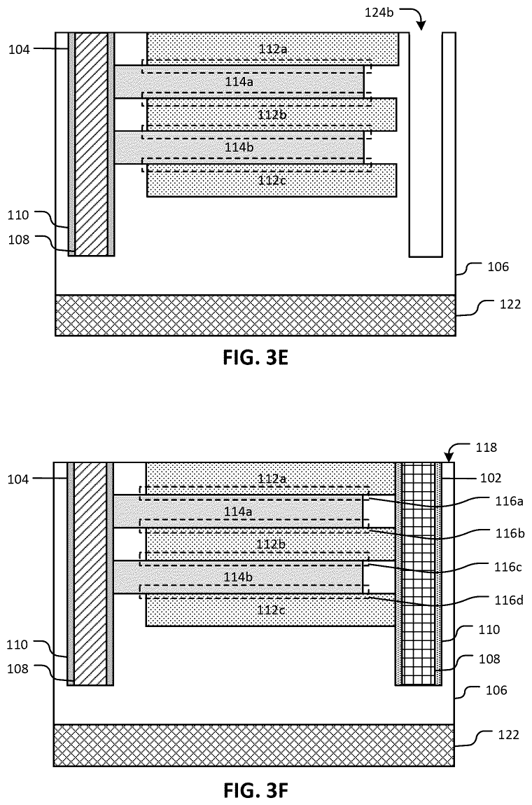

FIGS. 3A to 3F illustrate an example of a process for forming the APD 100 of FIG. 2. In FIG. 3A, a thickness of semiconductor material 106 is deposited over a semiconductor substrate 122. The semiconductor material of substrate 122 may be a lightly doped silicon with a dopant concentration on the order of 10¹⁵/cm³, for example. Other materials are possible.

The semiconductor material 106 may be an intrinsically doped material such as silicon that is grown on the substrate 122 using an epitaxial growth process. The semiconductor material 106 may have a dopant concentration that is about the same as that of the substrate 122. After deposition, the thickness of semiconductor material 106 may be planarized using a process such as chemical mechanical polishing (CMP).

Doped layer 112c is formed by implanting dopants onto the exposed surface of semiconductor material 106. The dopants may be implanted using a local doping process as known in the art to achieve a dopant concentration on the order of from 10¹⁷/cm³ to 10¹⁸/cm³.

Next, as shown in FIG. 3B, a second thickness of semiconductor material may be epitaxially grown over the doped layer 112c and planarized, and a second local doping process is performed to form doped layer 114b at a location that overlaps with and is laterally offset from doped layer 112c. The dopant type of doped layer 114b may be opposite to the dopant type of doped layer 112c, such that forming doped layer 114b also forms PN junction 116d. Referring to FIG. 3C The same process of epitaxial growth, planarization and local doping may be repeated to form doped layers 112b, 114a and 112a and PN junctions 116c, 116b and 116a. Each of the doped layers 112 and 114 may have the same width and thickness.

An opening 124a (e.g. a trench) is etched in a portion of the semiconductor material 106 next to the doped layers 112 and 114. The etching may be performed using a photoresist mask (not shown) as known in the art. Dopants are implanted into the sidewalls of the opening 124a using a process as known in the art, for example, an angled implantation process, to form doped sidewalls 110 for the second vertical conductive structure 104. After sidewall doping, the opening 124a is filled with conductive material 108 using a damascene process. When the conductive material is doped polysilicon, the polysilicon may be deposited using an in-situ doping process. The resulting structure after the planarization step of the damascene process is shown in FIG. 3D.

Similar processes are used to form the first vertical conductive structure 102. For example, as seen in FIGS. 3E and 3F, an opening 124b is etched in the semiconductor material 106, dopants are implanted into the sidewalls of the opening 124b, and a conductive material 108 is formed using a damascene process. When the conductive material 108 of vertical conductive structure 102 is a doped semiconductor material, the material may have the same type of dopants as doped layers 112, and the opposite dopant type to the conductive material 108 of vertical conductive structure 104. Additional structures (not shown) may be formed on incident surface 118 such as an anti-reflective coating, a lens, electrodes, a sealing layer, a protective layer, etc.

The process illustrated by FIGS. 3A to 3F is only one example, and other embodiments are possible. In another embodiment (not shown), a wafer comprising the APD 100 may be flipped, and substrate 122 may be partially or entirely removed using a thinning process to form a device in which incident surface 118 is at the bottom of the device with respect to the orientation shown in the figures. In other embodiments, the number and location of doped layers 112 and 114 may be varied to form a greater or fewer number of PN junctions 116 and to be sensitive to specific light frequencies. Persons of skill in the art will recognize that these and other variations are within the scope of the present disclosure.

FIG. 4 is a plan view of another embodiment of an APD device 100, and FIG. 5 is a cross-sectional view taken along A-A′ of FIG. 4. In the embodiment of FIG. 4, the first vertical conductive structure 102 has a pillar shape and is located in the center of the device. The pillar-shaped vertical conductive structure 102 is coupled to doped layers 112a, 112b, and 112c which surround the pillar. The pillar of vertical conductive structure 102 may have a rectilinear, polygonal or rounded (e.g. circular) cross-sectional shape with respect to a plan view.

The second vertical conductive structure 104 has a closed shape within an opening in the middle that surrounds the device, and is coupled to doped layers 114a and 114b. While the embodiment of FIG. 4 has a square shape, other rectilinear and polygonal shapes are possible, as are circular, oval or otherwise rounded shapes. PN junctions 116 are formed at interfaces between doped layers 112 and 114. For convenience of illustration, a portion of doped layers 114a are shown in FIG. 4 that would otherwise be obscured by semiconductor material 106.

The embodiment of FIG. 4 includes two guard rings 120. A first guard ring 120a is in a space between vertical conductive structure 104 and outer edges of doped layers 112, and a second guard ring 120b is in a space between pillar-shaped vertical conductive structure 102 and inner edges of doped layers 114. PN junctions 116 extend between the first guard ring 120a and the second guard ring 120b.

Apart from the shape, characteristics of the embodiment of FIG. 4 may be the same as those described above, including thicknesses, doping concentrations, the presence of doped sidewalls 110 in the vertical conductive structures 102 and 104, etc. The embodiment of FIG. 4 may be formed using similar techniques at the process described with respect to FIGS. 3A to 3F, except the opening 124b used to form vertical conductive structure 102 has a pillar shape.

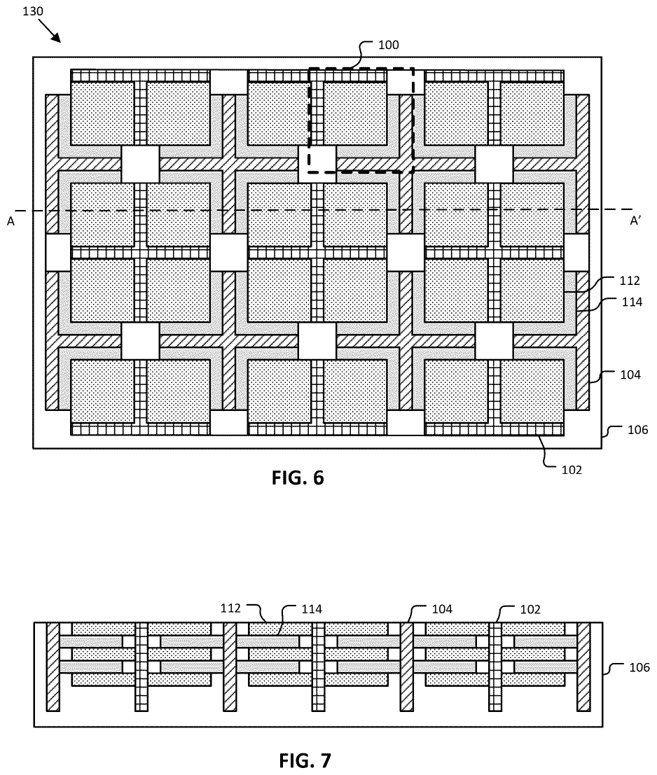

FIG. 6 is a plan view of a photodetector 130 with an array of APD devices 100, and FIG. 7 is a cross-sectional view taken along A-A′ of FIG. 6. Some features of the APD devices 100 in these figures, such as doped sidewalls, guard rings and PN junctions, are omitted for visual clarity, but such features may be present in an array.

In the photodetector of FIG. 6, each pixel may be associated with an APD device 100 that is similar to the embodiment shown in FIGS. 1 and 2, except that the vertical conductive structures 102 and 104 comprise trenches that are shared by multiple APD devices 100 (pixels). For example, vertical conductive structures at edges of the array have a “T” shape and are shared by two APD devices 100, while vertical conductive structures in the middle of the array have an “+” shape and are shared by four APD devices. In another embodiment, APD devices 100 with pillar-shaped vertical conductive structures 102 (as seen in FIG. 4) may be arranged in an array in a photodetector 130. In such an embodiment, adjacent pixels may share at least one portion of a trench-shaped vertical conductive structure 104, Persons of skill in the art will recognize that an array of APDs can be implemented in various ways in accordance with the technology of the present disclosure. A photodetector 130 may comprise an array of tens, hundreds or thousands of APD devices 100.

The photodetector 130 may comprise a control circuit configured to control operations of the APDs 100. The control circuit is electrically coupled to the APDs and may be configured to apply a bias voltage to the APDs for detection of a photon, sense an avalanche current generated from the APDs, quench avalanche current by adjusting the bias voltage, and restore the bias voltage to an operating level for detection of another photon.

Embodiments of the present disclosure represent improvements to APD technology. In embodiments, timing performance and sensitivity may be enhanced compared to conventional devices. Multiple junctions reduce drift and cause avalanches to occur quickly, and timing jitter may be reduced due to concentration of junctions. Sensitivity may be improved by detecting more wavelengths of light due to the depth and spacing between PN junctions. In addition, consistent avalanches may occur along the depth of an APD at a constant level.

In an embodiment with a plurality of interleaved doped layers 112 and 114, breakdown probability is high and can extend to a large depth proportional to the number of interleaved layers. A high volume of layers provides a high breakdown probability

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting. Steps within a method claim are not limited to the order in which they appear in the claim. For example, in a method claiming forming a first structure followed by forming a second structure, the second structure may be formed before the first structure within the scope of the claim. That is, no sequential order is necessarily implied by the order in which steps are listed.

1. An avalanche photodiode device comprising:
a first doped layer having a first doping type;
a second doped layer having a second doping type;
a third doped layer having the first doping type;
a first PN junction between the first doped layer and the second doped layer;
a second PN junction between the second doped layer and the third doped layer;
a first vertical conductive structure coupled to the first doped layer and the third doped layer; and
a second vertical conductive structure coupled to the second doped layer.

2. The avalanche photodiode device of claim 1, wherein the first vertical conductive structure is a first trench structure and the second vertical conductive structure is a second trench structure.

3. The avalanche photodiode device of claim 2, wherein the first trench structure is coupled to two sides of the first and third doped layers, and the second trench structure is coupled to two sides of the second doped layer.

4. The avalanche photodiode device of claim 1, wherein one of the first and second conductive structures has a trench shape, and the other of the first and second conductive structures has a pillar shape.

5. The avalanche photodiode device of claim 1, wherein one of the first and second vertical conductive structures is an anode, and the other of the first and second vertical conductive structures is a cathode.

6. The avalanche photodiode device of claim 1, wherein the first and second conductive structures comprise doped sidewalls and a conductive material between the doped sidewalls.

7. The avalanche photodiode device of claim 1, further comprising:
a fourth doped layer having the second doping type; and
a third PN junction between the third doped layer and the fourth doped layer.

8. The avalanche photodiode device of claim 7, further comprising:
a fifth doped layer coupled to the first vertical conductive structure; and
a fourth PN junction between the fourth doped layer and the fifth doped layer.

9. The avalanche photodiode device of claim 1, further comprising:
a guard ring between the first and second PN junctions and the first vertical conductive structure.

10. The avalanche photodiode device of claim 1, further comprising:
a guard ring between uncoupled edges of the first and third doped layers and the second vertical conductive structure, and between uncoupled edges of the second doped layer and the first vertical conductive structure.

11. The avalanche photodiode device of claim 1, wherein sidewalls of the first and second vertical conductive structures have a dopant concentration on the order of from 10¹⁸/cm³ to 10¹⁹/cm³, and the first, second, and third doped layers have a dopant concentration on the order of from 10¹⁷/cm³ to 10¹⁸/cm³.

12. A photodetector comprising at least one avalanche photodiode device, the at least one avalanche photodiode device comprising:
a first doped layer having a first doping type;
a second doped layer having a second doping type;
a third doped layer having the first doping type;
a first PN junction between the first doped layer and the second doped layer;
a second PN junction between the second doped layer and the third doped layer;
a first vertical conductive structure coupled to the first doped layer and the third doped layer; and
a second vertical conductive structure coupled to the second doped layer.

13. The photodetector of claim 12, wherein the first vertical conductive structure is a first trench structure and the second vertical conductive structure is a second trench structure.

14. The photodetector of claim 13, wherein the first trench structure is coupled to at least two sides of the first and third doped layers, and the second trench structure is coupled to at least two sides of the second doped layer.

15. The photodetector of claim 12, wherein one of the first and second conductive structures has a trench shape, and the other of the first and second conductive structures has a pillar shape.

16. The photodetector of claim 12, wherein the first and second conductive structures comprise doped sidewalls and a conductive material between the doped sidewalls.

17. The photodetector of claim 12, wherein the at least one avalanche photodiode device further comprises:
a fourth doped layer having the second doping type; and
a third PN junction between the third doped layer and the fourth doped layer.

18. The photodetector of claim 12, wherein the at least one avalanche photodiode device further comprises:
a guard ring between the first and second PN junctions and the first vertical conductive structure.

19. The photodetector of claim 12, wherein the at least one avalanche photodiode comprises an array of avalanche photodiodes, and at least two of the avalanche photodiodes in the array share the first vertical conductive structure as an anode or a cathode for the at least two avalanche photodiodes.

20. A method for forming an avalanche photodiode device, the method comprising:
forming a first doped layer having a first doping type;
forming a second doped layer having a second doping type;
forming a third doped layer having the first doping type;
forming a first vertical conductive structure coupled to the first doped layer and the third doped layer; and
forming a second vertical conductive structure coupled to the second doped layer and the fourth doped layer,
wherein a first PN junction is located between the first doped layer and the second doped layer, and
a second PN junction is located between the second doped layer and the third doped layer.
